(19) United States
(12) Patent Application Publication
(10) Pub. No.: US 2017/0287873 A1
(43) Pub. Date: Oct. 5, 2017

(54) ELECTRONIC ASSEMBLY COMPONENTS WITH CORNER ADHESIVE FOR WARPAGE REDUCTION DURING THERMAL PROCESSING

(71) Applicants: Santosh Sankarasubramanian, Chandler, AZ (US); Hong Xie, Phoenix, AZ (US); Nachiket R. Raravikar, Gilbert, AZ (US); Steven A. Klein, Chandler, AZ (US); Pramod Malatkar, Chandler, AZ (US)

(72) Inventors: Santosh Sankarasubramanian, Chandler, AZ (US); Hong Xie, Phoenix, AZ (US); Nachiket R. Raravikar, Gilbert, AZ (US); Steven A. Klein, Chandler, AZ (US); Pramod Malatkar, Chandler, AZ (US)

(21) Appl. No.: 15/084,032

(22) Filed: Mar. 29, 2016

(51) Int. Cl. H01L 25/065; H01L 25/00; H01L 23/00

(52) U.S. Cl. CPC H01L 25/0657; H01L 24/32; H01L 24/17; H01L 25/50; H01L 24/81; H01L 2225/06517; H01L 2225/06513; H01L 2224/8122; H01L 2224/1712; H01L 2224/32059; H01L 2224/32106

(57) ABSTRACT

An IC package, an electronic assembly, and methods of preventing warpage of components of an electronic assembly during fabrication of the electronic assembly are shown. An IC package including an adhesive disposed at or near at least one of four corners of a die of the IC package is shown. An electronic assembly including an IC package that includes an adhesive disposed at or near at least one of four corners of a second surface of a first substrate is shown. Methods of preventing warpage of components of an electronic assembly during fabrication of the electronic assembly that include applying an adhesive to at least one of four corners of a first surface of a first component are shown.

### TECHNICAL FIELD

Embodiments described herein generally relate to microelectronic structures, and, more particularly, to the fabrication of integrated circuit packages and electronic assemblies.

### BACKGROUND

Fabrication of an integrated circuit (IC) package, is a multi-step process, which includes steps such as patterning, deposition, etching, and metallization. In the final processing steps, a resulting IC die can be separated and packaged. One type of IC packaging technique is referred to as “flip chip” packaging. In flip chip packaging, a first plurality of solder bump structures (e.g., solder bumps, balls, pads, pillar bumps (e.g., copper pillar bumps), etc.) of a generally uniform size are positioned between the die and a substrate, and the die and substrate are heated to similar temperatures. The die is then lowered onto the substrate, in order to mechanically and electrically couple the die to the substrate. Heat is applied via a solder reflow process to re-melt the solder bump structures and attach the die to the substrate. Attachment of the die to the substrate (i.e., primary substrate), to form the IC package, is referred to as a “first level interconnection” (FLI). The IC package may further be underfilled with a non-conductive adhesive, or over-molded, to strengthen the mechanical connection between the die and the substrate.

One or more such IC packages can be physically and electrically coupled to a secondary substrate, such as a printed circuit board (PCB) or a motherboard. Attachment of the IC package(s) directly to the secondary substrate, such as by soldering, is referred to as a “second level interconnection” (SLI). Alternatively, an IC die and patch combination can be coupled to an interposer, and the combination of the IC package and the interposer can then be placed in a socket or coupled to a PCB. Attachment of the IC die and patch combination to the interposer, such as by soldering, is referred to as a “middle (or mid-) level interconnection” (MLI). The resulting package is called a “Patch-on-Interposer” (PoINT) package.

Surface mount technology (SMT) is a widely known technique that can be used in forming SLIs, for example. One of the conventional methods for surface-mounting a die on a substrate employs a ball-grid-array (BGA). Electrically conductive terminals of a die are soldered directly to corresponding lands on the surface of the substrate using an array of reflowable solder bump structures (i.e., solder bumps, solder balls). SMT, using a BGA, can be used to form a SLI by coupling one or more IC packages to a secondary substrate, such as a PCB or motherboard. Solder bumps, for example, can be employed between lands on the IC package and corresponding lands on the PCB.

A BGA can also be used in forming a FLI to attach a die to another die, or a die to a substrate to form an IC package or “BGA package.” A BGA can also be used to form an MLI in PoINT packages.

### BRIEF DESCRIPTION OF THE DRAWINGS

FIG. 1 shows a cross-section of an example of an IC package.

FIG. 2 shows a cross-section of an example of an electronic assembly.

FIG. 3 shows a cross-section of an example of an IC package.

FIG. 4 shows a cross-section of an example of an electronic assembly.

FIG. 5 shows a view of the electronic assembly in FIG. 4 taken at dashed line 5-5.

FIG. 6 shows a block diagram of an example of an electronic system.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

FIG. 1 shows a cross-section of an example of an IC package 100. IC package 100 includes a die 110 mounted in flip-chip orientation with its active side facing downward to couple with an upper surface of a substrate 120, through a number of first level interconnections 112, such as solder bump structures, solder balls or solder bumps. A BGA of such first level interconnections 112 can be used to form IC package 100, for example. Also, in FIG. 1, the substrate 120 shows a second level of interconnections 122, such as solder balls, on its opposite surface for mating with an additional packaging structure, such as a PCB (not shown).

Die 110 generates its heat from internal structure, including wiring traces, located near its active side; however, a significant portion of the heat is dissipated through its back side 114. Heat that is concentrated within the die is dissipated to a large surface that is in contact with the die in the form of an integrated heat spreader 130. A thermal interface material 140 can be provided between the die 110 and integrated heat spreader 130. In one embodiment, to further dissipate heat from the integrated heat spreader 130, a heat sink 150 optionally having fins 152 can be coupled to the integrated heat spreader 130.

Manufacturing of an IC package, using SMT, can involve multiple thermal cycling (or processing) steps. For instance, a substrate may be heated to add solder balls (e.g., flip-chip or controlled collapse chip connection (C4) solder balls) to the substrate. The substrate may again be heated one or more times for die placement and solder reflow. Another thermal cycle may be added if epoxy, for example, is used in the assembly process as an underfill. Yet another thermal cycle may be used to incorporate the IC package into an electronic assembly. These multiple thermal cycles can lead to warpage of components of the IC package. Such warpage is caused by a difference in coefficients of thermal expansion (CTE) between one component and another. Warpage is increasingly a problem as IC packages are being made thinner because the thinness, such as of the substrate, can result in the IC packages being flexible.

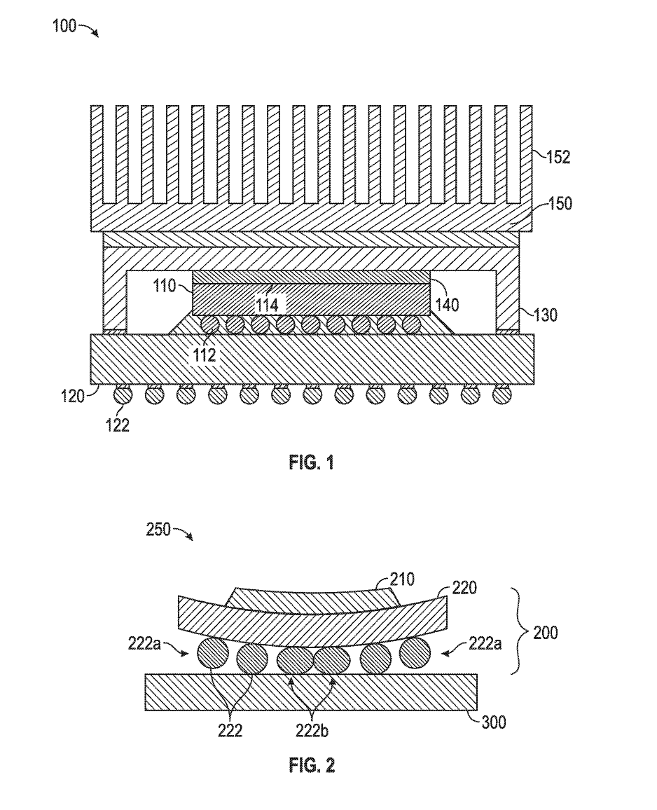

FIG. 2 shows a cross-section of an example of an electronic assembly 250 including an IC package 200. Electronic assembly 250 shows an example of warpage. IC package 200 is shown including a die 210 attached to a substrate 220, which is attached to a secondary substrate 300, such as a PCB. As a result of SMT, including solder reflow processing, warpage of an IC package, such as IC package 200, can occur, as shown. A shape inflection of the IC package 200 having a concave shape with respect to the secondary substrate 300, as shown, is possible. Other possible shapes of the IC package 200 or the secondary substrate 300 due to warpage can result, however.

Warpage can pose a problem in forming interconnections in IC packages, as shown in FIG. 2. Warpage refers to a bending or twist or general lack of flatness in an overall IC package or an electronic assembly component, including particularly a plane formed by solder joint locations. A lack of flatness in an IC package, for example, can cause various problems such as poor soldered joints between the IC package and a mounting surface, or substrate, poor or no contact at the solder joints, undesirably pillowed joints, or intermittent contact at the solder joints. Lack of flatness can occur where the entire package warps so that it is curved or bent or otherwise non-flat. Warpage can also be problematic for attachments of other components in electronic assemblies.

Warpage can cause stress to be placed on solder, such as in solder balls in a BGA, that connects lands, or contacts (not shown in FIG. 2), and can cause solder interconnections to be broken or never made. For example, as shown in FIG. 2, the result of the IC package having a concave shape, rather than a generally flat or planar shape, can be that solder balls 222 do not contact the PCB 300. When a solder ball near a side or edge of an IC package, for example, does not contact the PCB, it is referred to as a non-contact opening (NCO) and is indicated by 222a. In addition, warpage can cause an IC package or an electronic assembly to fail. For example, due to the warpage, solder balls at or near the center of the die or substrate, such as solder balls indicated by 222b, can bridge to, or contact, each other. This is referred to as solder ball (or bump) bridging (SBB). SBB can result in failure of an IC package or an electronic assembly.

The inventors have recognized that it can be beneficial to reduce warpage of an IC package, or other components, during manufacture or assembly of electronic assemblies. Inhibiting warpage and, for example, the occurrence of NCOs or SBB, during the manufacture or assembly of electronic assemblies can increase yield and thereby increase profits. The present subject matter can help provide a solution to this problem by adding adhesive at any or all of the four corners (or other locations) of a BGA (or land) side of a component, prior to SMT or solder reflow processing in order to couple components together and prevent warpage. The adhesive can provide a constraining force between an IC package, for example, and a PCB.

One additional benefit to the presence of the adhesive between components in an electronic assembly is that solder joint reliability is increased. This can be important if the electronic assembly undergoes a drop or a shock event. Another additional benefit is that other methods of reducing or preventing warpage may not be necessary. For example, during fabrication of an electronic assembly, other components, such as molds or stiffeners, are generally used to maintain planarity of components. These other components add to the cost of manufacture of electronic assemblies. Eliminating the need for additional components to prevent warpage can result in a cost savings.

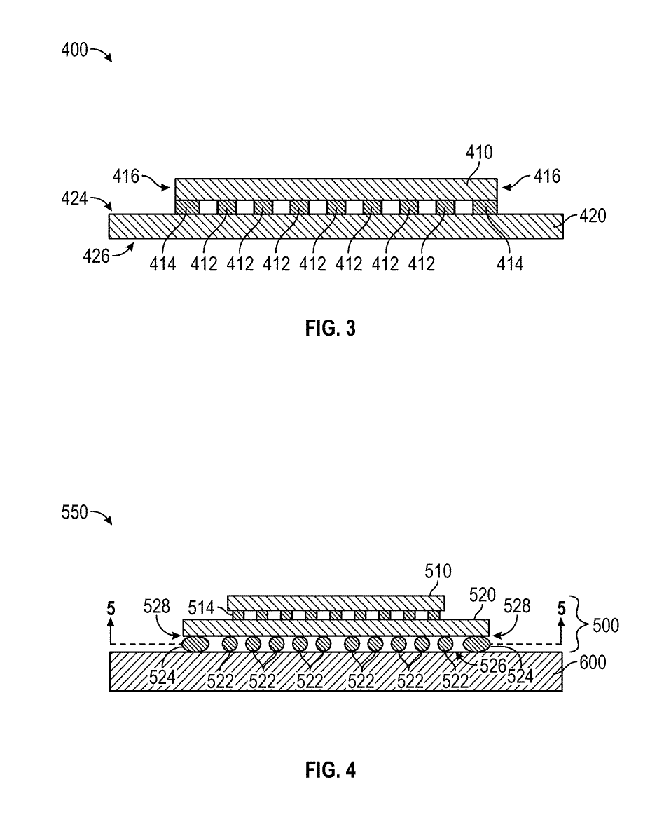

FIG. 3 shows a cross-section of an example of an IC package 400, including a die 410 and a substrate 420. Substrate 420 includes a first surface 424 and a second opposite surface 426. Die 410 can be attached, such as by using flip chip packaging, to the first surface 424 of the substrate 420 at an elevated temperature. A plurality of first level interconnections, such as solder balls 412, can be used to couple the die 410 to the first surface 424 of the substrate 420. The number of solder balls 412 included in FIG. 3 is illustrative, and any number of solder balls can be used.

During solder reflow processing temperatures, the die 410 and the substrate 420 can have different warpages, which can cause the die 410 to warp away from the substrate 420, possibly preventing electrical connections from being formed between the die 410 and the substrate 420. However, as shown in FIG. 3, an adhesive 414 is located between the die 10 and the substrate 420 at or near corners 416 of the die 410. The adhesive 414 can be placed on at least one corner 416 or up to all four corners 416 (not all shown in FIG. 3) of the die 410 before the die 410 can be attached to the substrate 420. In addition, more adhesive (not shown) could have been added to the die 410 in locations other than the four corners, prior to solder reflow processing, in order to additionally prevent warpage. The adhesive 414 can prevent or inhibit at least one or up to four of the corners 416 of the die 410 from lifting, curving or warping away from the substrate 420. Improving attachment of the die 410 to the substrate 420, by including adhesive 414, can also reduce the chance of flexing and warpage of the substrate 420.

FIG. 4 shows a cross-section of an example of an electronic assembly 550 including an IC package 500 coupled or attached to a secondary substrate 600, such as a PCB. The figure shows the electronic assembly 550 after solder reflow processing. The IC package 500 was attached to the secondary substrate 600 prior to solder reflow processing and remains attached thereafter. IC package 500 further includes a die 510 and a substrate 520 coupled by first level interconnections 514. A plurality of solder balls 522 are shown between a bottom surface 526 of the substrate 520 of IC package 500 and the secondary substrate 600. The number of solder balls 522 included in FIG. 4 is illustrative, and any suitable number or pattern of solder balls 522 can be used.

The plurality of interconnections, or solder balls 522, in FIG. 4 can be considered to be second level interconnections if secondary substrate 600 is a PCB, for example. If, however, secondary substrate is an interposer, the plurality of interconnections, or solder balls 522, would be considered middle level interconnections. A combination of the IC package 500 (including a patch as substrate 520) and an interposer 600, such as a PoINT package, could be placed in a socket (not shown) or attached to a PCB (not shown).

As shown in FIG. 4, an adhesive 524 can be located between the IC package 500 and the secondary substrate 600 at or near corners 528 of the substrate 520 portion of IC package 500. The adhesive 524 can be placed on at least one corner 528 or up to all four corners 528 (not all shown in FIG. 4) of the secondary substrate 600 before the IC package 500 can be attached to the secondary substrate 600. The adhesive 524 can prevent or inhibit at least one or up to four of the corners 528 of the IC package 500 from lifting, curving or warping away from the secondary substrate 600. As shown, the adhesive 524 do not merge or interfere with the solder balls 522. The adhesive 524 at or near the corners 528 can reduce the chance of NCOs. Improving attachment of the IC package 500 to the secondary substrate 600, by including adhesive 524, can also reduce the chance of flexing and warpage of the secondary substrate 600. A reduction in the chance of warpage of electronic assembly 550 can reduce the chance of SBB. In addition, more adhesive (not shown) could have been added to the bottom surface 526 of substrate 520 in locations other than the four corners, prior to solder reflow processing, in order to additionally prevent warp age.

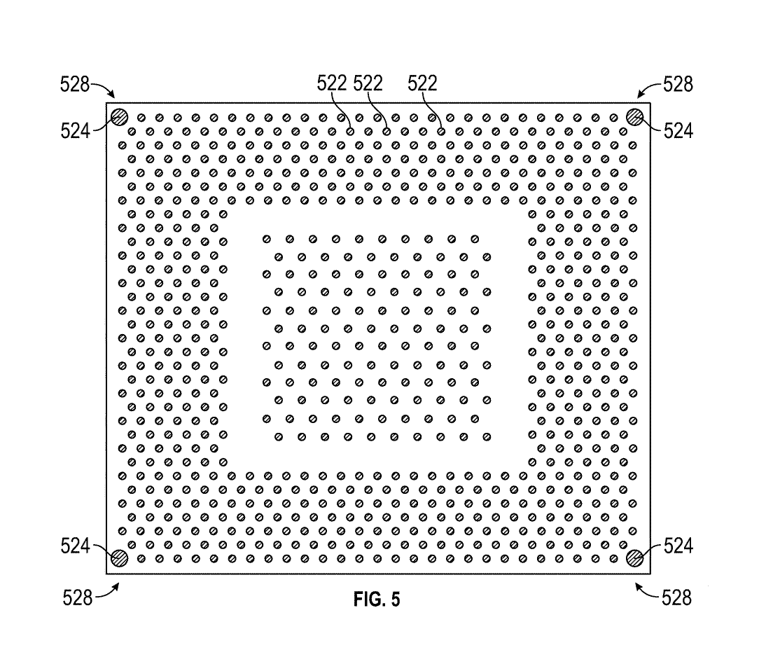

FIG. 5 shows a view of the electronic assembly 550 (in FIG. 4) taken at dashed line 5-5. FIG. 5 includes an illustrative pattern and number of solder balls 522. The solder balls 522 can be arranged in a two-dimensional array. Adhesive 524, as shown, can be located at or near the corners 528 of substrate 520 on the land or BGA side of IC package 500 (as in FIG. 4). The adhesive 524 can be placed such as to not interfere with solder balls 522 and their resulting interconnections. Although adhesive drops or spots are shown in the figures, it is contemplated that alternative forms of adhesive can be used. For example, an adhesive film can be used.

The embodiments described herein can also be used with other sets of interconnections that are used in IC package assembly. For example, the adhesive in the embodiments described herein can also be used to prevent warpage during the formation of logic to memory (LMI) interconnections between a logic die and a memory die, or during the formation of memory to memory (MMI) interconnections between a first memory die and a second memory die.

Dies 410, 510 can be any type of electronic circuit capable of being packaged. Examples of such dies include, without limitation, a central processing unit (CPU) die, a system-on-chip (SoC) die, a microcontroller die, a microprocessor die, a graphics processor die, a digital signal processor die, a volatile member die (e.g., dynamic random-access memory (DRAM die, DRAM cubes)), a non-volatile memory die (e.g., flash member, magneto-resistive RAM), and the like. Dies 410, 510 may be a custom circuit or any application-specific integrated circuit, such as a communications circuit for use in wireless devices such as cellular telephones, pagers, portable computers, two-way radios, and similar electronic systems.

Substrates 420, 520, 600 can be any type of substrate capable of being used for packaging ICs or other components included in an electronic assembly. Examples of such substrates include, without limitation, dielectric carriers (e.g., ceramics, glass), semiconductor wafers, PCBs, interposers, patches, and the like.

Lands, or contacts, (not shown) can be located on dies 410, 510 or substrates 420, 520, 600 and can be made, for example, of gold, silver, copper, tin and alloys comprised of any combination of tin, bismuth, lead and/or indium. The solder balls 412, 522 can electrically couple lands (not shown) on the dies 410, 510 with substrates 420, 520, respectively, or can couple lands (not shown) on the bottom surface 526 of substrate 520 with secondary substrate 600. The solder used can be any suitable solder material.

The adhesive used can be dispensed at room temperature at or near corners of a BGA side, or land side, of a component, such as an IC package, prior to thermal processing. The adhesive can be pre-dispensed onto the BGA side of such components, or can be applied at any time prior to thermal processing. Although the location of the adhesive is shown herein as being at or near the corners, the adhesive can alternatively or additionally be applied at other locations for warpage reduction. The adhesive can also be applied such that, upon thermal processing, the adhesive does not interfere with the interconnections between electronic assembly components.

A liquid adhesive can be used, such as to form drops or spots at the corners of a component. Alternatively, a film adhesive can be used. A cover tape can be applied to the film adhesive, which can be removed just prior to thermal processing. Other forms of adhesive are also contemplated.

The adhesive can be any fast-curing adhesive that cures after thermal processing, such as during solder reflow processing used in SMT. Alternatively, the adhesive can have sufficient tackiness after thermal processing, such as to provide a constraining force between two components above a flux activation temperature of about 150 degrees Celsius.

One example of an adhesive can be an epoxy, or any polyepoxide. However, the adhesive can also be any other suitable adhesive, such as any acrylate, any polyimide, or any polyamide. The adhesive can also be a thermo-plastic adhesive, such as ethylene vinyl acetate or any polyurethane compound, for example Generally, adhesives having a high modulus-high adhesion and a high glass transition temperature, such as 180 to 200 degrees Celsius, for example, are preferred, such that modulus of the adhesive stays high for a significant portion of SMT.

The adhesive can be used, for example, to keep an IC package attached to a PCB, such as in FIG. 4, so as to keep the shape of the IC Package close to that of the PCB. At high temperatures, such as 200 to 260 degrees Celsius, for example, the adhesive can prevent the IC package from bending away from the PCB, thus preventing NCOs at the corners of the IC package, as well as SBB at the center of the IC package, and thus improving SMT yield.

Other embodiments pertain to a method of fabricating electronic assemblies, or components thereof, in which warpage can be reduced, inhibited or prevented. The methods described herein can be used, for example, during SLI attachment, FLI die attachment, die to die attachment, MLI ball attachment for PoINT packages, die to interposer attachment, or SMT of individual packages onto system in package (SIP), for example. However, the described methods can be used in other processes of fabricating an electronic assembly, in order to prevent warpage.

An embodiment is a method of preventing warpage of components of an electronic assembly during fabrication of the electronic assembly. The method can include, for example: providing a first component having a first surface and a second surface; applying a first plurality of solder bump structures to the first surface of the first substrate; applying an adhesive to at least one of four corners of the first surface of the first component; providing a second component; placing the second component in contact with the plurality of solder bump structures and the adhesive on the first surface of the first substrate; and thermally processing the first component and the second component after the second component is in contact with the plurality of solder bump structures and the adhesive on the first surface of the first substrate.

Depending on the components being assembled together, the first substrate can be a die or an IC package substrate, for example, and the second substrate can be a PCB, a patch, an interposer or a die, for example. The adhesive can be a liquid adhesive, a film adhesive or any other suitable adhesive. The adhesive can also, or alternatively, be applied to other locations on the first surface of the first substrate.

Using SMT and SLI, for an example, adhesive, such as in drop form, can be located on corners of an IC package substrate on a land side, along with a BGA of solder balls. As the IC package is heated during SMT reflow, the adhesive can start curing, which causes the adhesive to become tacky and start to hold the IC package to a PCB, for example As the temperature rises, an IC package can change shape, such as to flip from a concave shape to a convex shape, or vice versa. As long as the adhesive used can reach sufficient tackiness by the time that the processing temperature reaches about 180 degrees Celsius, the IC package can then have a force constraining it to the PCB. From about 180 degrees Celsius to a peak reflow temperature of about 260 degrees Celsius, the adhesive should preferably be tacky enough and stiff enough to hold the IC package to the PCB, as the IC package could undergo shape inflection. Shape inflection of the IC package, for example, could cause corners of the IC package to pull away from the PCB. If the adhesive can hold the IC package generally planar, overall warpage can be reduced, thereby increasing SMT yield.

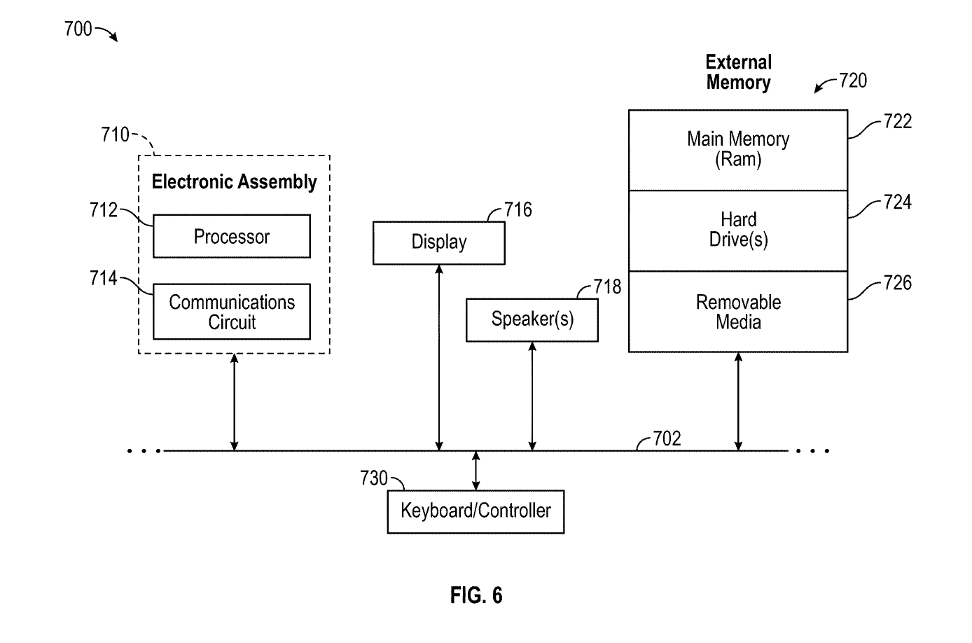

An example of an electronic device using electronic or semiconductor chip assemblies as described in the present disclosure is included to show an example of a higher level device application incorporating the embodiments described above. FIG. 6 is a block diagram of an example of an electronic device 700 incorporating an IC package and/or method in accordance with at least one embodiment. Electronic device 700 is merely one example of an electronic system in which embodiments described above can be used. Examples of electronic devices 700 include, but are not limited to personal computers, tablet computers, mobile telephones, game devices, MP3 or other digital music players, etc. In this example, electronic device 700 comprises a data processing system that includes a system bus 702 to couple the various components of the system. System bus 702 provides communications links among the various components of the electronic device 700 and can be implemented as a single bus, as a combination of busses, or in any other suitable manner

An electronic assembly 710 is coupled to system bus 702. The electronic assembly 710 can include any circuit or combination of circuits. The adhesive described in the embodiments above may be incorporated into the electronic assembly 710. In one embodiment, the electronic assembly 710 includes a processor 712 which can be of any type. As used herein, “processor” means any type of computational circuit, such as but not limited to a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), multiple core processor, or any other type of processor or processing circuit.

Other types of circuits that can be included in electronic assembly 710 are a custom circuit, an application-specific integrated circuit (ASIC), or the like, such as, for example, one or more circuits (such as a communications circuit 714) for use in wireless devices like mobile telephones, personal data assistants, portable computers, two-way radios, and similar electronic systems. The IC can perform any other type of function.

The electronic device 700 can also include an external memory 720, which in turn can include one or more memory elements suitable to the particular application, such as a main memory 722 in the form of random access memory (RAM), one or more hard drives 724, and/or one or more drives that handle removable media 726 such as compact disks (CD), flash memory cards, digital video disk (DVD), and the like.

The electronic device 700 can also include a display device 716, one or more speakers 718, and a keyboard and/or controller 730, which can include a mouse, trackball, touch screen, voice-recognition device, or any other device that permits a system user to input information into and receive information from the electronic device 700.

To better illustrate the method and apparatuses disclosed herein, a non-limiting list of embodiments is provided here:

Example 1 includes an IC package, including: an integrated circuit die having four corners; a first substrate having a first surface and a second surface; a first plurality of solder bump structures electrically coupling the die to the first surface of the first substrate; and an adhesive disposed at or near at least one of the four corners of the die of the integrated circuit package, wherein the adhesive is disposed between the die and the first substrate.

Example 2 includes the IC package of example 1, wherein the adhesive includes at least one drop of adhesive.

Example 3 includes the IC package of any one of examples 1-2, in combination with a second substrate, wherein a second plurality of solder bump structures electrically couples the second substrate to the second surface of the first substrate.

Example 4 includes the IC package of any one of examples 1-3, wherein the second substrate is a printed circuit board.

Example 5 includes the IC package of any one of examples 1-4, wherein the second substrate is an interposer.

Example 6 includes the IC package of any one of examples 1-5, wherein the adhesive is an adhesive tape.

Example 7 includes the IC package of any one of examples 1-6, wherein the first substrate is a second die.

Example 8 includes the IC package of any one of examples 1-7, wherein the adhesive is applied to other locations on the die besides at least one of the four corners.

Example 9 includes the IC package of any one of examples 1-8, wherein the adhesive is applied at all four corners of the die.

Example 10 includes an electronic assembly, including: an integrated circuit including: an integrated circuit die; a first substrate having a first surface and a second surface and four corners; and a first plurality of solder bump structures electrically coupling the die to the first surface of the first substrate; a second substrate; a second plurality of solder bump structures electrically coupling the second surface of the first substrate to the second substrate; and an adhesive disposed at or near at least one of the four corners of the second surface of the first substrate, wherein the adhesive is disposed between the first substrate and the second substrate and is configured to couple the first substrate and the second substrate to prevent warpage of the electronic assembly.

Example 11 includes the electronic assembly of example 10, wherein the adhesive includes at least one drop of adhesive.

Example 12 includes the electronic assembly of any one of examples 10-11, wherein the second substrate is a printed circuit board.

Example 13 includes the electronic assembly of any one of examples 10-12, wherein the second substrate is an interposer.

Example 14 includes the electronic assembly of any one of examples 10-13, wherein the adhesive is an adhesive tape.

Example 15 includes the electronic assembly of any one of examples 10-14, wherein the adhesive is applied to other locations on the second surface of the first substrate besides at least one of the four corners.

Example 16 includes the electronic assembly of any one of examples 10-15, wherein the adhesive is applied at all four corners of the second surface of the first substrate.

Example 17 includes a method of preventing warpage of components of an electronic assembly during fabrication of the electronic assembly, including: providing a first component having a first surface and a second surface; applying a first plurality of solder bump structures to the first surface of the first substrate; applying an adhesive to at least one of four corners of the first surface of the first component; providing a second component; placing the second component in contact with the plurality of solder bump structures and the adhesive on the first surface of the first substrate; and thermally processing the first component and the second component after the second component is in contact with the plurality of solder bump structures and the adhesive on the first surface of the first substrate.

Example 18 includes the method of example 17, wherein the first component is a die or an IC package substrate.

Example 19 includes the method of any one of examples 17-18, wherein the second component is a PCB, a patch, an interposer or a die.

Example 20 includes the method of any one of examples 17-19, wherein the adhesive is a liquid adhesive or a film adhesive.

These and other examples are intended to provide non-limiting examples of the present subject matter—it is not intended to provide an exclusive or exhaustive explanation. The Description of Embodiments is included to provide further information about the present methods and apparatuses.

The above Description of Embodiments includes references to the accompanying drawings, which form a part of the Description of Embodiments. The drawings show, by way of illustration, specific embodiments in which the subject matter can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

For expository purposes, the term “horizontal” as used herein is defined as a plane parallel to the plane or surface, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures.

The term “on” means that there is direct contact between elements. The term “directly on” means that there is direct contact between one element and another element without an intervening element.

The above Description of Embodiments is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Description of Embodiments, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Description of Embodiments, with each claim standing on its own as a separate embodiment, and it is contemplated that such embodiments can be combined with each other in various combinations or permutations. The scope of the subject matter should be determined with reference to the appended claims, along with the full scope of equivalents to which such claims are entitled.

1. An integrated circuit (IC) package, comprising
an integrated circuit die having four corners;
a first substrate having a first surface and a second surface;
a first plurality of solder bump structures electrically coupling the die to the first surface of the first substrate; and
an adhesive disposed only at or near the four corners of the die of the integrated circuit package, wherein the adhesive is disposed between the die and the first substrate and is configured to couple the die and the first substrate during high temperature processing and to limit bridging of the solder bump structures and warpage of the integrated circuit package.

2. The integrated circuit package of claim 1, wherein the adhesive includes at least one drop of adhesive.

3. The integrated circuit package of claim 1, in combination with a second substrate, wherein a second plurality of solder bump structures electrically couples the second substrate to the second surface of the first substrate.

4. The integrated circuit package of claim 3, wherein the second substrate is a printed circuit board.

5. The integrated circuit package of claim 1, wherein the second substrates an interposer.

6. The integrated circuit package of claim 1, wherein the adhesive is an adhesive tape.

7. The integrated circuit package of claim 1, wherein the first substrate is a second die.

8-9. (canceled)

10. An electronic assembly comprising:
an integrated circuit including:
an integrated circuit die;
a first substrate having a first surface and a second surface and four corners; and
a first plurality of solder bump structures electrically coupling the die to the first surface of the first substrate;
a second substrate;
a second plurality of solder bump structures electrically coupling the second surface of the first substrate to the second substrate; and
an adhesive disposed only at or near the four corners of the second surface of the first substrate, wherein the adhesive is disposed between the first substrate and the second substrate and is configured to couple the first substrate and the second substrate to prevent warpage of the electronic assembly during high temperature processing of the electronic assembly.

11. The electronic assembly of claim 10, wherein the adhesive includes at least one drop of adhesive.

12. The electronic assembly of claim 10, wherein the second substrate is a printed circuit board.

13. The electronic assembly of claim 10, wherein the second substrate is an interposer.

14. The electronic assembly of claim 10, wherein the adhesive is an adhesive tape.

15-16. (canceled)

17. A method of preventing warpage of components of an electronic assembly during fabrication of the electronic assembly, comprising:
providing a first component having a first surface and a second surface;
applying a first plurality of solder bump structures to the first surface of the first substrate;
applying an adhesive only at or near four corners of the first surface of the first component in order to couple the first component and a second component during high temperature processing and to limit bridging of the solder bump structures and warpage of the first and the second components;
providing the second component;
placing the second component in contact with the plurality of solder bump structures and the adhesive on the first surface of the first substrate; and
thermally processing the first component and the second component after the second component is in contact with the plurality of solder bump structures and after the adhesive on the first surface of the first substrate is cured and has coupled the first component and the second component together.

18. The method of claim 17, wherein the first component is a die or an IC package substrate.

19. The method of claim 17, wherein the second component is a PCB, a patch, an interposer or a die.

20. The method of claim 17, wherein the adhesive is a liquid adhesive or a film adhesive.

21. The integrated circuit package of claim 1, wherein the adhesive is selected from the group consisting of an epoxy, a polyepoxide, an acrylate, a polyimide, and a polyamide.

22. The electronic assembly of claim 10, wherein the adhesive is selected from the group consisting of an epoxy, a polyepoxide, an acrylate, a polyimide, and a polyamide.

23. The method of claim 17, wherein the adhesive is selected from the group consisting of an epoxy, a polyepoxide, an acrylate, a polyimide, and a polyamide.
